(19) United States
(12) Patent Application Publication
(10) Pub. No.: US 2006/0118406 A1
(43) Pub. Date: Jun. 8, 2006

(54) SPUTTERED TRANSPARENT CONDUCTIVE FILMS

(75) Inventors: Alan E. Delahoy, Rocky Hill, NJ (US); Sheyu Guo, Wallingford, PA (US); Robert B. Lyndall, Titusville, NJ (US); J.A. Anna Selvan, Bryn Mawr, PA (US)

Correspondence Address: BROOKS KUSHMAN P.C., 1000 TOWN CENTER, TWENTY-SECOND FLOOR, SOUTHFIELD, MI, 48075, US

(73) Assignee: ENERGY PHOTOVOLTAICS, INC.

(21) Appl. No.: 11/275,079

(22) Filed: Dec. 8, 2005

Related U.S. Application Data
(60) Provisional application No. 60/634,231, filed on Dec. 8, 2004.

(51) Int. Cl. C23C 14/00

(52) U.S. Cl. 204/192.12; 204/298.02

(57) ABSTRACT

A hollow cathode sputtering apparatus and related method for introducing dopants into a sputtered coating is provided. The method utilizes a sputter reactor which includes a cathode channel that allows a gas stream to flow therein and a flow exit end from which gases may flow out of and towards a substrate to be coated. The cathode channel as used in the invention is defined by a channel defining surface that includes at least one target material. The sputter reactor further includes a dopant target positioned to provide dopant atoms to the gas stream when the gas stream is flowed through the cathode channel.

### CROSS-REFERENCE TO RELATED APPLICATIONS

This application claims the benefit of U.S. provisional application Ser. No. 60/634,231 filed Dec. 8, 2004.

### BACKGROUND OF THE INVENTION

1. Field of the Invention

The present invention relates to hollow cathode sputtering methods and apparatuses for depositing doped materials on a substrate.

2. Background Art

The introduction of dopant atoms into materials such as transparent conducting oxides (“TCOs”) presents several technical difficulties. Indium oxide, for example, can be doped by introducing metals such as Sn, Zr, W, Nb, Ti, Mo, and Ta. The dopant atom concentration for optimal doping generally lies somewhere in the 0.5-10 atomic % range. The valence of the host cation in In₂O₃ is In³⁺. For a metal to serve as a doping cation it should have a higher valence than that of the host ion for which it substitutes. It is also desirable that it have a diameter equal to or smaller than that of the host ion to suppress its incorporation as an interstitial atom. Thus Sn⁴⁺ is a particularly suitable doping ion in In₂O₃ with electrical resistivities as low as about 1-2×10⁻⁴ Ω-cm being widely reported for tin-doped indium oxide (“ITO”).

If the TCO is deposited by planar magnetron sputtering from a ceramic target in an in-line sputtering system onto a moving substrate, use of a second sputtering cathode (fitted with a planar metal target of the dopant element) results in the sequential deposition of the oxide and the metal rather than simultaneous deposition. The dopant metal would therefore have to be incorporated into the ceramic target. Such targets are expensive. It is perhaps conceivable that angled cathodes could be used so that the material fluxes from the cathodes overlap and deposition is simultaneous. However, cross-contamination of the targets seem unavoidable in such designs. If reactive sputtering is performed to form the oxide (using a metallic target in a partial pressure of oxygen) either a composite target could be fabricated (a metal alloy target or a configuration in which a strip of the dopant metal is placed alongside a slightly smaller metal target) or again two separate targets could be used. In the former case, the resulting composition would very roughly be expected to be in the ratio of the respective target areas. However, there is no flexibility in choice of dopant ratio. To change the composition, a new dual target assembly would have to be fabricated having a different area ratio. Furthermore, in both cases (dual and separate target cases), oxygen would react with the dopant target or portion of target resulting in a reduced sputter yield and an unpredictable sputtering rate.

Titanium is another possible dopant for indium oxide. However, little is known about the titanium doping of indium oxide. The lowest resistivity for In₂O₃:Ti (ITiO) that has been reported appears to be about 4.0×10⁻ Ω-cm. However, some researchers were unable to obtain doping with Ti. These latter investigators claimed titanium does not function as a dopant in indium oxide.

Various solar designs include a transparent conducting electrode through which light passes to reach the active layers of the solar cell. The active layers may consist of nc-Si:H or a tandem structure of a-Si:H followed by nc-Si:H. To achieve the highest short-circuit current density from the cell, the TCO should ideally possess high transparency in the visible region, low electrical resistivity (4×10⁻⁴ Ω-cm), a morphology or surface texture that promotes light trapping, and minimal free carrier absorption in the near infrared region (up to λ=1200 nm). Heretofore, a transparent conducting oxide possessing each of these features is unavailable. Doped ZnO films (ZnO:Al or ZnO:B), for example, can be prepared in a form that possesses adequate visible transparency, electrical conductivity, and surface texture. However, this material has only the modest carrier mobility of ZnO which leads to an inadequately small free carrier absorption.

Accordingly, there exists a need in the prior art for improved methods and apparatuses for depositing doped materials, and in particular, to doped material that may function as transparent electrical conductors.

### SUMMARY OF THE INVENTION

The present invention solves one or more problems of the prior art by providing in one embodiment a reactive-environment, hollow cathode sputtering (“RE-HCS”) method and related hollow cathode sputtering reactor for introducing dopants into a sputtered coating. The method utilizes a sputter reactor which includes a cathode channel that allows a gas stream to flow therein. Moreover, the cathode channel has a flow exit end from which gases may flow out of and towards a substrate to be coated. Significantly, the cathode channel as used in the invention is defined by a channel defining surface that includes at least one target material. The sputter reactor further includes a dopant target positioned to provide dopant atoms to the gas stream when the gas stream is flowed through the cathode channel. During execution of the method of the invention, a gas is flowed through the cathode channel such that the gas emerges from the flow exit. While the gas is flowing, a plasma is generated which sputters material off of the channel-defining surface and the dopant target to form a gaseous mixture containing target atoms and dopant atoms. After emerging from the cathode channel the gaseous mixture of the dopant atoms, target atoms, and the working gas mixes with a reactive gas and is transported to the substrate.

Advantageously, the method of the invention uses in one variation metal wires as the dopant target. Such wires are both readily available and inexpensive. Moreover, the ratio of the surface area of the wire to the internal area of the main cathode targets are automatically in an appropriate range for doping (at the level of a few atomic percent). Utilization of wire circumvents the need for machining a planar target to a specific size as is often required in sputtering methods and apparatus. The use of wire offers numerous other advantages which include easy selection of the surface area of the wire by choice of wire diameter, ease of switching between dopants by simply changing the wire, no active cooling of the wire is required (provided it is a refractory metal, or provided it is operated below its melting point). Finally, the apparatus and methods of the invention result in a more effective substitution and doping process. Although not limiting the invention to any particular mechanism for this improvement, dopant atoms in passing through the intense hollow cathode discharge are likely to be activated thereby having sufficient energy for doping. Finally, because of the proximity of the high plasma density in the hollow cathode the present invention allows for dopant material to be sputtered as lower voltages and at higher current densities than can be achieved in conventional non-magnetron sputtering.

In another embodiment of the invention, an alternative cathode design for use in the sputter apparatus set forth above is provided. In one aspect, this alternative design is mounted on a chamber flange for easy installation and removal from a vacuum chamber. In another aspect, this alternative cathode design includes a reactive gas channel that is integral to the cathode such that the reactive gas is introduced into the sputter-coating system at a position proximate to the flow exit.

### BRIEF DESCRIPTION OF THE DRAWINGS

FIG. 1 is a schematic of an embodiment of the sputtering system of the present invention using a wire or rod as a dopant source;

FIG. 2 is a schematic of the driver for introducing fresh wire into the hollow cathode sputtering apparatus of the invention;

FIG. 3 is a schematic of a perspective view of the alternative cathode design of the invention;

FIG. 4A is a schematic of a top view of the alternative cathode design of the invention;

FIG. 4B is a schematic of a cross-section of the alternative cathode design of the present invention; and

FIG. 5 is a perspective view of another embodiment of the invention for introducing two reactive gases.

### DETAILED DESCRIPTION OF THE PREFERRED EMBODIMENT(S)

Reference will now be made in detail to the presently preferred compositions or embodiments and methods of the invention, which constitute the best modes of practicing the invention presently known to the inventors.

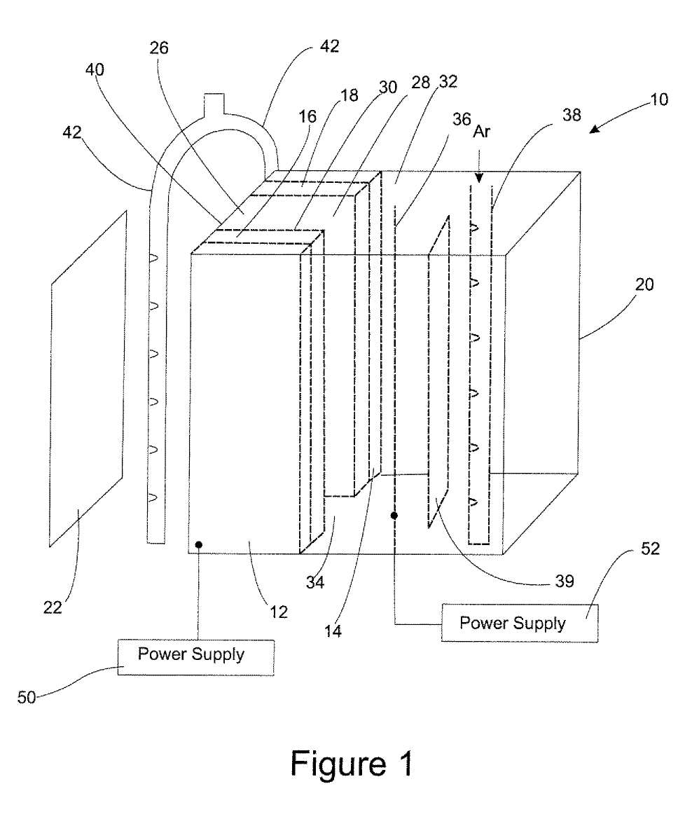

With reference to FIG. 1, a schematic of the sputter apparatus for introducing doping elements into a coating applied to a substrate of the present invention is provided. Sputtering apparatus 10 includes water cooled cathode sections 12, 14 which are attached to targets 16, 18. Targets 16, 18 are contained with gas box 20. Targets 16, 18 include one or more components that are incorporated into the coating which is sputtered onto substrate 22. Targets 16, 18 typically comprise a metal or metal alloy. Suitable materials included in targets 16, 18 include, for example, zinc, copper, aluminum, silicon, tin, indium, magnesium, titanium, chromium, molybdenum, nickel, yttrium, zirconium, niobium, cadmium, and mixtures thereof. Cathode channel 26 is defined by main target surfaces 28, 30 and walls 32, 34 of gas box 20. Dopant target 36 is positioned within gas box 20. Working gas is introduced into gas box 20 via gas manifold 38 which is positioned within gas box 20. Plate 39 is a physical structure to mix up the gases. Typically, the working gas is an inert gas such as argon. The sputter apparatus also includes anode. The anode can be the sputter chamber or a grounded metal object in the sputter chamber (e.g., gas manifold 38 or a grounded rod in the gas box) In one variation, dopant target 36 is positioned between working gas manifold 38 and cathode channel 26. In another variation of the invention, dopant target 36 is positioned within cathode channel 26 but before flow exit 40. Placement of dopant target 36 ideally should be such that reactive gases don't reach dopant target 36 so that it remains metallic. In a variation of the present invention, gas manifold 38 can be configured as a source of non-laminarly flowing working gas as described in U.S. patent application Ser. No. 10/635,344, the entire disclosure of which is hereby incorporated by reference. Sputter reactor 10 also includes reactive gas manifold 42 for introducing a reactive gas into the sputter coating reactor. Reactive gas manifold 42 positioned outside of the channel from which the gaseous mixture emerges. Examples of reactive gases that may be introduced into the sputter reactor include, for example, gases that comprise an atom selected from the group consisting of oxygen, nitrogen, fluorine, selenium, sulfur, iodine, hydrogen, carbon, boron, and phosphorus.

Although dopant target 36 may be virtually any shape, including a plate, dopant target 36 comprises a dopant-containing wire or a dopant-containing rod. The dopant-containing wire or rod may advantageously be moveable such that alternative surfaces of the wire may be exposed in the sputter reactor. The length of the exposed portion of dopant target 36 is about equal to the length of gas box 20. Other portions of the wire can be covered by ceramic tubes. Co-doping with different elements can be performed through provision of separate wires. Moreover, dopant target 36 is composed of any material that is desired to be used as a dopant in a sputtered coating that can be incorporated or formed into a wire or rod. For example, the dopant-containing wire or rod comprises a metal selected from the group consisting of Sn, Zr, W, Nb, Ti, Mo, Ta, and combinations thereof. Each of the sputter reactor components set forth above are typically placed within a vacuum chamber.

During operation of sputtering apparatus 10, a working gas is flowed into gas box 20 from gas manifold 38. Targets 16, 18 are powered by first plasma generating power source 50 which generates a first plasma that ionizes the working gas causing material to be sputtered off of targets 16, 18. Similarly, dopant target 36 is powered by second plasma generating power source 52 to generate a second plasma in the vicinity of the dopant target 36. This second plasma may cause matter to be sputtered off of the dopant target 36. Each of these power supplies provide either a DC potential, a DC potential with a superimposed AC potential, or a pulsed DC potential. In a variation of this embodiment, the plasma generating power source is a pulsed DC power source that is an asymmetric bipolar pulsed DC power supply. Material sputters off of dopant target 36 and targets 16, 18, and is transported through cathode channel 26. Reactive gas introduced into the vacuum chamber from reactive gas manifold 42 mixes with the sputtered material. This reactive gaseous mixture containing sputter target atoms, dopant atom, working gas, and reactive gas is then transported to substrate 22 onto which a film is deposited. The direction of the gas flow is such that atoms of the main target (targets 16, 18) are not deposited on the surface dopant source 36, thereby eliminating cross contamination and rate drift for dopant incorporation. Also, deposition of some atoms of the dopant element on the main target occurs, the amount is limited because of the limited flux of the dopant and because of the gas flow.

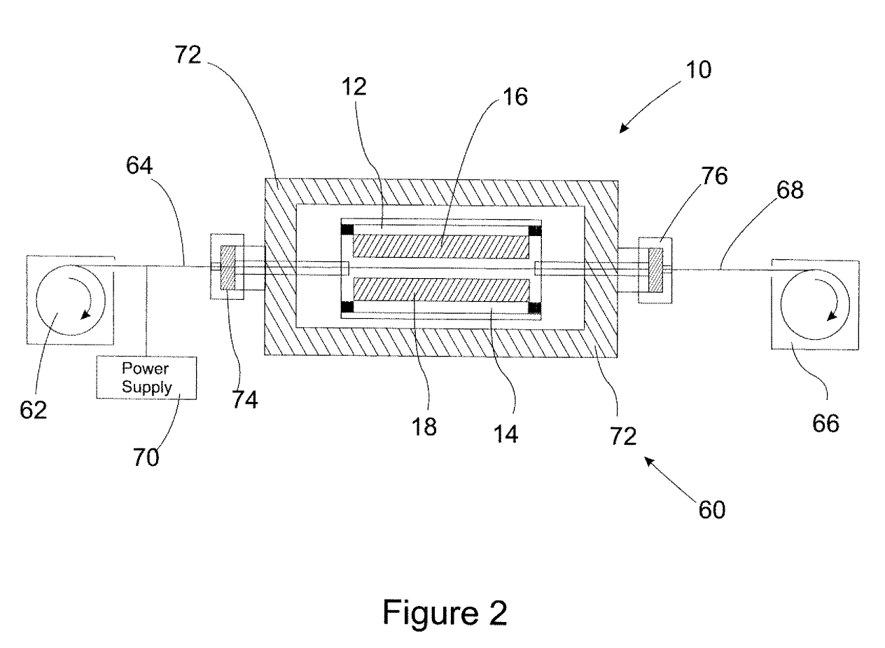

With reference to FIG. 2, a schematic of a driver for introducing fresh wire (dopant source) when needed into the hollow cathode sputtering apparatus 10 is provided. Such a driver is particularly useful for long-term coating operations. Driver 60 includes supply reel 62 from which fresh dopant wire 64 is feed into sputter reactor 10 and take-up reel 66 onto which spent wire 68 is spooled. Supply reel 62 and take-up reel 66 are motorized and powered by power supply 70. Fresh wire may be introduced continuously into sputtering apparatus 10 or it may be introduced from time to time when needed. Fresh wire 64 is introduced into vacuum chamber 72 via vacuum port 74 which has a mechanism for forming a vacuum seal to the wire (i.e., rubber O-ring) while spent wire 68 is removed through vacuum port 74.

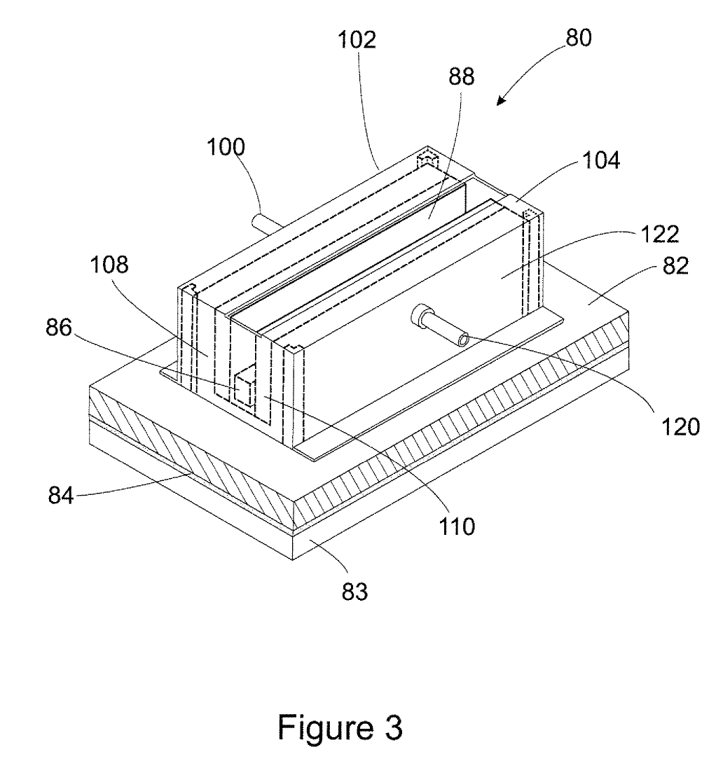

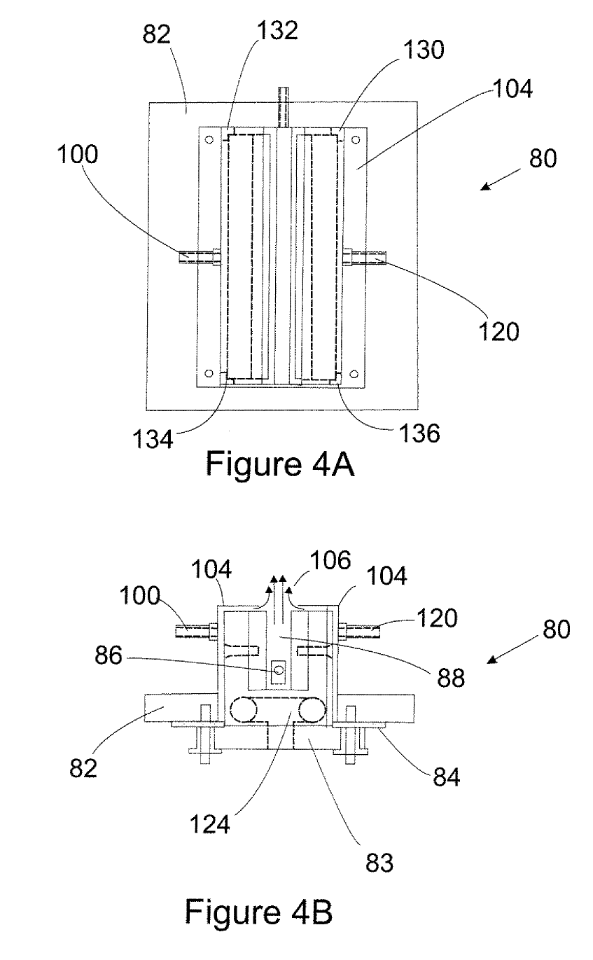

In another embodiment of the invention, an alternative cathode design that is mounted on a chamber flange for easy installation and removal is provided. The disadvantages of the original cathode design are now described. To ensure that the working gas passes through cathode channel 26, gas box 20 which is a gas-tight enclosure surrounds gas manifold 38. Gas box 20 tends to be bulky and desirably floats electrically. Moreover, if gas box 20 is not grounded it is difficult to mount the cathode. Accordingly, ceramic insulators are used to mount gas box 20 to the cathode. Such insulators are used to define the ends of the cavity and around the electrical connections to the cathode. In addition, insulated water lines and an insulated working gas line must penetrate the vacuum chamber wall. This implies that the water fittings should be on the air side of the vacuum chamber. It is desirable that no ceramic insulators be used, since these are expensive and difficult to machine. These disadvantages provide a motivation for the alternative design described by FIGS. 3, 4A, and 4B.

With reference to FIGS. 3, 4A, and 4B, schematics of the alternative cathode of this embodiment are provided. Cathode assembly 80 penetrates an aperture in the chamber wall 82. A seal is effected between flange 83 of cathode assembly 80 and chamber wall 82 by using gasket 84 (such as a silicone rubber vacuum gasket.) Gas manifold 86 is placed within cathode channel 88 in contrast to FIG. 1 where gas manifold 38 is located behind cathode channel 26. This placement of gas manifold 86 requires that little or no sputtering of gas manifold 86 occur, that spurious deposits of target material neither short the cathode to ground nor block the gas apertures in gas manifold 86, and that the gas flow pattern is conducive to efficient removal of sputtered atoms. It is noteworthy that this design is of all-metal construction (except for the silicone vacuum gasket) and completely eliminates the need for ceramic insulators. In this design the working gas is distributed first from a line of holes in gas manifold 86. The working gas then impinges on a plate, and issues sideways from between the plate and the manifold to impinge directly on the target pieces. This arrangement accomplishes the desirable condition of non-laminar gas flow that enhances removal of sputtered atoms from the cavity, thereby maximizing deposition rate as disclosed in U.S. patent application Ser. No. 10/635,344. When gas manifold 86 is grounded, the distance between gas manifold 86 and the surrounding cathode surfaces is small enough (less than the dark space distance) so that a discharge does not occur between them. It is preferred that the gas manifold is left electrically floating.

In yet another embodiment of the invention, the source of reactive gas includes a reactive gas channel that is integral to the cathode such that the reactive gas is introduced into the sputter-coating system at a position proximate to the flow exit. Specifically, the reactive gas flows between the cathode body and the dark shield and is uniformly introduced in the vicinity of the exit of the cathode channel. With reference to FIGS. 3, 4A and 4B schematics of this embodiment are provided. Cathode assembly 80 introduces the reactive gas (i.e., oxygen) via first fitting 100 attached to side 102 of dark shield 104, and constraining it to flow out from under dark shield 104 and across channel exit 106. Similarly, reactive gas is also introduced via second fitting 120 attached to side 122 of dark shield 104. Cooling channels 124 are used to cool the cathode of the present invention. When the reactive gas is oxygen, the method of introducing the reactive gas of this embodiment has improved efficiency in that less oxygen is needed, for example, to produce ZnO films. Moreover, the distribution of oxygen in the long direction of the cavity is more uniform than that obtained with an end-fed linear manifold. Distribution in the cross-direction is also more uniform because of better gas stream mixing. The integral gas channel of this embodiment avoids deposition of material around, and eventual blocking of, the exit holes in the type of manifold that holes to distribute gas.

The configuration of this embodiment may be used to introduce and distribute two reactive gases that cannot be pre-mixed at high pressure without unwanted reactions occurring. For example, ZnO:B is formed by sputtering targets 108, 110 made of Zn, with oxygen introduced into first fitting 100 attached to side 102 of dark shield 104, B₂H₆ in Ar introduced into second fitting 120 on the side 122 of dark shield 104. Corner partitions 130-136 are inserted at the ends of the cathode to prevent the two gases from mixing. Each gas is thereby distributed along the length of the cathode and constrained to flow out towards the cavity exit from the respective openings between the shield and the target pieces. The gases enter the main working gas stream from opposite directions. This invention enables the two separate and external gas manifolds normally required to be dispensed with. Again, the method eliminates coating and blockage of reactive gas manifolds.

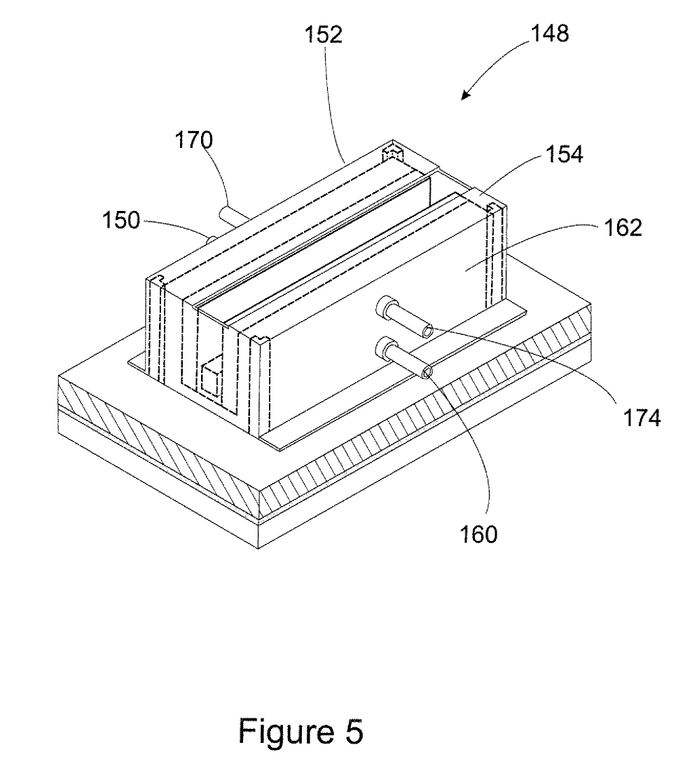

With reference to FIG. 5, a variation is provided for introducing two reactive gases. In this variation, cathode assembly 148 introduces a first reactive gas (i.e., oxygen) via first fitting 150 attached to side 152 of dark shield 154 and second fitting 160 attached to side 162 of dark shield 154. A second reactive gas is introduced by third fitting 170 and fourth fitting 174. T-joints may be used to split the reactive gases as needed in the configuration of this embodiment.

In yet another embodiment of the present invention, a method for sputtering a doped coating onto a substrate using the sputter reactor set forth above is provided. Specifically, the sputter reactor includes a vacuum chamber, an anode, and a cathode. The cathode includes a channel-defining surface that defines a cathode channel and a flow exit end. Moreover, the channel-defining surface includes at least one target material and the cathode channel is adapted to allow a gas stream to flow therein. The sputter reactor further includes a dopant target positioned to provide dopant atoms to the gas stream when the gas stream is flowed through the cathode channel. The sputter reactor also includes one or more plasma generating power sources. Typically, separate power supplies will be in communication with the at least one target material and with the dopant target. The method of the invention includes the step of flowing gas through the cathode channel. A plasma is generated such that material is sputtered off the at least one target material of the channel-defining surface and the dopant target to form a gaseous mixture containing target atoms and dopant atoms that are transported to the substrate. A portion of the gas flowing through the channel is a non-laminarly flowing gas. The details of the sputter reactor and its components are set forth above.

The method of the invention are advantageously used to form doped indium oxide. To form such an oxide, the reactive gas comprises oxygen, the at least one target material comprises indium, and the dopant target comprises a metal selected from the group consisting of Sn, Zr, W, Nb, Ti, Mo, Ta, and combinations thereof. In particular, the present invention discloses a method for efficiently doping indium oxide with Ti. Efficiently as used in this context means that the titanium doped indium oxide has a resistivity less than about 5.0×10⁻³ Ω-cm. In other variations, the titanium doped indium oxide has an electrical resistivity less than about 1.0×10⁻³ Ω-cm. In still other variations, the titanium doped indium oxide has an electrical resistivity less than about 5.0×10⁻⁴ Ω-cm. Typically, the titanium doped indium oxide also has an average visible light transmission greater than about 70%. In other variations, the titanium doped indium oxide also has an average visible light transmission greater than about 80%. In still other variations, the titanium doped indium oxide also has an average visible light transmission greater than about 85%.

In still another embodiment of the invention, a textured transparent conducting structure is provided. The textured ZnO composition comprises a textured layer of intrinsic-ZnO (“i-ZnO”) disposed over a substrate. This i-ZnO layer is in turn over-coated with a high mobility transparent conducting oxide (“TCO”). Adequate texture is achieved either by deposition or by anisotropically etching a fiber texture oriented ZnO film that is conveniently prepared by sputtering. Because of the lack of doping, this sublayer possesses no free carrier absorption. Examples of suitable high mobility TCO includes In₂O₃:Mo, or more desirably In₂O₃:Ti, In₂O₃:Zr, or other material. As a result of the high mobility (>80 cm²/Vs), this sub-layer has almost no free carrier absorption in the near infrared region.

The following examples illustrate the various embodiments of the present invention. Those skilled in the art will recognize many variations that are within the spirit of the present invention and scope of the claims.

Table 1 provides the deposition parameter of various doped indium oxides made by the method and apparatus of the present invention. In the case of titanium doping, a Ti wire as the dopant source is configured as set forth above in FIG. 1. Significantly, a film resistivity for In₂O₃:Ti of 1.710×10⁻⁴ Ω-cm with about 88% optical transmission. Under slightly different deposition conditions, the transmission can be improved to 91% at the expense of a slightly increased resistivity of 2.2×10⁻⁴ Ω-cm. The transmission of In₂O₃:Ti was found to be superior to that of In₂O₃:Mo. This result is probably related to the transparent nature of Ti₂O₃ compared to the colored nature of MoO₃. Because of its greater transmission we consider In₂O₃:Ti to be superior to In₂O₃:Mo. Furthermore, the carrier mobility in In₂O₃:Ti was measured to be 80 cm²/Vs, similar to that of In₂O₃:Mo, but higher than that of ITO (mobility 25-50 cm²/Vs). We believe the use of reactive-environment, hollow cathode sputtering to form In₂O₃:Ti is a notable invention, because of the record low resistivity obtained for the material, and because of its excellent transmission. The trade-off between transmission and resistivity is adjusted via the oxygen flow rate, increasing the oxygen flow improves the transmission, but increases the resistivity. The larger oxygen flow makes the film (and possibly some dopant atoms) fully oxidized, the oxygen vacancies are decreased and so the carrier density is decreased. Finally, the resistivity of zirconium doped indium oxide made by the method of the invention is about 2.2×10⁻⁴ Ω-cm which is lower than previously reported resistivities for this material.

TABLE 1
Deposition of In₂O₃:M, where M is a dopant selected from Mo, Nb, Ti, W, or Zr

| | | Power | Power | | | | | | |
|---|---|---|---|---|---|---|---|---|---|
| | Wire | applied | applied | | Ar | | Film | Film | Film |
| | diameter | to main | to wire | Tₛ | flow | Pressure | thickness | resistivity | transmittance |
| Dopant | (in) | target (W) | (W) | (° C.) | (slm) | (mTorr) | (Å) | (×10⁻⁴ Ω-cm) | (%) |
| none | — | 240 | — | 254 | 2 | 150 | 5330 | 5.6 | 93 |
| Mo | 0.03 | 240 | 30 | 254 | 2 | 150 | 4390 | 1.6 | 85 |
| Nb | 0.04 | 250 | 45 | 260 | 2 | 120 | 8600 | 2.8 | 89 |
| Ti | 0.035 | 240 | 40 | 300 | 2 | 170 | 5450 | 1.7 | 88 |
| Ti | 0.035 | 240 | 50 | 250 | 1.5 | 140 | 3620 | 2.4 | 91 |
| W | 0.03 | 240 | 60 | 250 | 2 | 150 | 5850 | 2.1 | 74 |
| Zr | 0.02 | 240 | 60 | 250 | 2 | 150 | 5600 | 2.2 | 87 |

While embodiments of the invention have been illustrated and described, it is not intended that these embodiments illustrate and describe all possible forms of the invention. Rather, the words used in the specification are words of description rather than limitation, and it is understood that various changes may be made without departing from the spirit and scope of the invention.

What is claimed is:

1. A method for sputtering a doped coating onto a substrate, the method comprising:
a) providing a sputter reactor comprising:
a cathode channel that allows a gas stream to flow therein and having a flow exit end, the cathode channel being defined by a channel defining surface, wherein the channel defining surface includes at least one target material; and
a dopant target positioned to provide dopant atoms to the gas stream when the gas stream is flowed through the cathode channel;
b) flowing a gas through the channel, such that the gas emerges from the flow exit;
c) generating a plasma, wherein material is sputtered off the channel-defining surface and the dopant target to form a gaseous mixture containing target atoms and dopant atoms that are transported to the substrate.

2. The method of claim 1 wherein the dopant target comprises a dopant-containing wire or a dopant-containing rod.

3. The method of claim 2 wherein the dopant-containing wire is moveable such that alternative surfaces of the wire may be exposed in the sputter reactor.

4. The method of claim 2 wherein the dopant target comprises a metal selected from the group consisting of Sn, Zr, W, Nb, Ti, Mo, Ta, and combinations thereof.

5. The method of claim 1 wherein a portion of the gas flowing through the channel is a non-laminarly flowing gas.

6. The method of claim 1 wherein the dopant target is positioned upstream of the channel exit.

7. The method of claim 1 wherein the at least one target material comprises a metal or metal alloy.

8. The method of claim 1 wherein the at least one target material comprises a component selected from the group consisting of zinc, copper, aluminum, silicon, tin, indium, magnesium, titanium, chromium, molybdenum, nickel, yttrium, zirconium, niobium, cadmium, and mixtures thereof.

9. The method of claim 8 further comprising introducing a reactive gas into the sputter coating reactor.

10. The method of claim 9 wherein the reactive gas is introduced at a position located outside of the channel from which the gaseous mixture emerges.

11. The method of claim 9 wherein the reactive gas comprises an atom selected from the group consisting of oxygen, nitrogen, fluorine, selenium, sulfur, iodine, hydrogen, carbon, boron, and phosphorus.

12. The method of claim 9 wherein the reactive gas comprises oxygen, the at least one target material comprises indium, and the dopant target comprises a metal selected from the group consisting of Sn, Zr, W, Nb, Ti, Mo, Ta, and combinations thereof.

13. The method of claim 12 wherein the dopant target comprises Ti.

14. The method of claim 1 wherein the substrate is pre-coated with an undoped zinc oxide layer.

15. A doped metal oxide formed by the process of claim 1.

16. A method for sputtering a doped coating onto a substrate, the method comprising:
a) providing a sputter reactor comprising:
a vacuum chamber;
an anode;
a cathode having a channel-defining surface that defines a cathode channel and a flow exit end, wherein the channel-defining surface includes at least one target material and the cathode channel is adapted to allow a gas stream to flow therein, and
a dopant target positioned to provide dopant atoms to the gas stream when the gas stream is flowed through the cathode channel;
a first plasma generating power source in communication with the anode and cathode,
a second plasma generating power source in communication with the dopant target,
wherein the anode, the cathode, and the dopant target are positioned within the vacuum chamber;
b) flowing gas through the channel;
c) generating a plasma, wherein material is sputtered off the channel-defining surface and the dopant target to form a gaseous mixture containing target atoms and dopant atoms that are transported to the substrate.

17. The method of claim 16 wherein the dopant target comprises a dopant-containing wire or a dopant-containing rod.

18. The method of claim 17 wherein the dopant-containing wire is moveable such that alternative surfaces of the wire may be exposed in the sputter reactor.

19. The method of claim 17 wherein the dopant target comprises a metal selected from the group consisting of Sn, Zr, W, Nb, Ti, Mo, Ta, and combinations thereof.

20. The method of claim 16 wherein a portion of the gas flowing trough the channel is a non-laminarly flowing gas.

21. The method of claim 16 wherein the at least one target material comprises a metal or metal alloy.

22. The method of claim 16 wherein the first and second plasma generating power sources are each independently selected from a power source selected from the group consisting of power sources that provide a DC potential, power sources that provide a DC potential with a superimposed AC potential and power sources that provide a pulsed DC potential.

23. The method of claim 16 wherein the first and second plasma generating power sources are each independently selected from the groups consisting of asymmetric bipolar pulsed DC power supplies.

24. A sputter-coating system comprising:
a vacuum chamber;
an anode;
a cathode having a channel-defining surface that defines a cathode channel and a flow exit end, wherein the channel-defining surface includes at least one target material and the cathode channel is adapted to allow a gas stream to flow therein;
a dopant target positioned to provides dopant atoms to the gas stream when the gas stream is flowed through the cathode channel, wherein the anode, the cathode, and the dopant target are positioned within the vacuum chamber;
a first plasma generating power source in communication with the anode and cathode; and
a second plasma generating power source in communication with the dopant target, wherein the dopant target, the anode and cathode are adapted to generate a plasma whereby material is sputtered off the at least one target material and the dopant target to form a gaseous mixture containing target atoms and dopant atoms that are transported to the substrate.

25. The sputter-coating system of claim 24 further comprising a source of non-laminarly flowing working gas.

26. The sputter-coating system of claim 24 wherein the dopant target is positioned upstream of the channel exit.

27. The sputter-coating system of claim 24 wherein the at least target material comprises a metal or a metal alloy.

28. The sputter-coating system of claim 27 wherein the at least one target material includes a component selected from the group consisting of zinc, copper, aluminum, silicon, tin, indium, magnesium, titanium, chromium, molybdenum, nickel, yttrium, zirconium, niobium, cadmium, and mixtures thereof.

29. The sputter-coating system of claim 24 wherein the dopant target comprises a dopant-containing wire or a dopant-containing rod.

30. The sputter-coating system of claim 28 further comprising a driver that introduces the dopant target into the sputter-coating system when needed.

31. The sputter-coating system of claim 24 further comprising a source of a reactive gas.

32. The sputter-coating system of claim 31 wherein the source of reactive gas comprises a reactive gas channel that is integral to the cathode such that the reactive gas is introduced into the sputter-coating system at a position proximate to the flow exit.

33. The sputter-coating system of claim 32 wherein the reactive gas flows uniformly between the cathode body and the dark shield.

34. The sputter-coating system of claim 24 wherein the first and second plasma generating power sources are each independently selected from a power source selected from the group consisting of power sources that provide a DC potential, power sources that provide a DC potential with a superimposed AC potential, and power sources that provide a pulsed DC potential.

35. The sputter-coating system of claim 24 wherein the first and second plasma generating power sources are each independently selected from groups consisting of asymmetric bipolar pulsed DC power supplies.
